(19) United States
(12) Patent Application Publication
(10) Pub. No.: US 2014/0048946 A1
(43) Pub. Date: Feb. 20, 2014

(54) SENSOR PACKAGES AND METHOD OF PACKAGING DIES OF VARIOUS SIZES

(71) Applicants: Philip H. Bowles, Fountain Hills, AZ (US); Scott M. Hayes, Chandler, AZ (US)

(72) Inventors: Philip H. Bowles, Fountain Hills, AZ (US); Scott M. Hayes, Chandler, AZ (US)

(73) Assignee: FREESCALE SEMICONDUCTOR, INC., Austin, TX (US)

(21) Appl. No.: 13/588,205

(22) Filed: Aug. 17, 2012

(51) Int. Cl. H01L 23/48; H01L 21/56

(52) U.S. Cl. 257/774; 438/107; 257/E21.504; 257/E23.011

(57) ABSTRACT

A method (112) of forming a sensor panel (146) that includes an array (144) of sensor structures (22, 24) encapsulated in a mold material (148) and forming a controller panel (158) that includes an array (156) of controller dies (26) encapsulated in a mold material (160). The arrays (144, 156) are arranged so that locations of the sensor structures (22, 24) correspond with locations of the controller dies (26). The controller panel (158) is bonded (162) to the sensor panel (146) to form a stacked panel structure (164). After bonding, methodology (112) entails forming (178) conductive elements (84) on the controller dies (26), removing (174) material sections (126, 142, 168) from the controller panel 158 and the sensor panel (146) to expose bond pads (42, 58), forming (178) electrical interconnects (80), applying (182) packaging material (90), and singulating (196) the stacked panel structure (164) to produce sensor packages (20, 104).

### TECHNICAL FIELD OF THE INVENTION

The present invention relates generally to semiconductor packaging. More specifically, the present invention relates to wafer level semiconductor packaging for forming sensor packages in which semiconductor dies are of various sizes.

### BACKGROUND OF THE INVENTION

Microelectronic device technology has achieved wide popularity in recent years, as it provides a way to make very small electronic and mechanical structures and integrate these structures on a single substrate using conventional batch semiconductor processing techniques. While such microelectronic devices are becoming mainstream technologies, cost effectively packaging them in semiconductor packages for manufacture and ease of use remains challenging.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, the Figures are not necessarily drawn to scale, and:

FIG. 1 shows a top view of an exemplary sensor package in accordance with an embodiment;

FIG. 2 shows a side view of the sensor package along section lines A-A in FIG. 1;

FIG. 3 shows a diagram and associated equations exemplifying various sizes of components within the sensor package;

FIG. 4 shows a side view of a sensor package in accordance with another embodiment;

FIG. 5 shows a flowchart of a packaging process for fabricating the sensor packages;

FIG. 6 shows a top view of a sensor wafer structure used in connection with the packaging process;

FIG. 7 shows a partial side view of the sensor wafer structure of FIG. 6;

FIG. 8 shows a side view of a sensor structure produced following dicing of the sensor wafer structure of FIG. 6;

FIG. 9 shows a top view of a sensor wafer structure used in connection with the packaging process;

FIG. 10 shows a partial side view of the sensor wafer structure of FIG. 9;

FIG. 11 shows a side view of a sensor structure produced following dicing of the sensor wafer structure of FIG. 9;

FIG. 12 shows a top view of an array of the sensor structures of FIGS. 8 and 11 used in connection with the packaging process;

FIG. 13 shows a top view of a panel of the sensor structures of FIGS. 8 and 11 produced in accordance with the packaging process;

FIG. 14 shows a top view of a controller wafer used in connection with the packaging process;

FIG. 15 shows an enlarged partial top view of the controller wafer;

FIG. 16 shows side view of a controller element produced following dicing of the controller wafer of FIG. 14;

FIG. 17 shows a top view of an array of the controller dies of FIG. 16 used in connection with the packaging process;

FIG. 18 shows a top view of a panel of the controller dies of FIG. 16 produced in accordance with the packaging process;

FIG. 19 shows a partial side sectional view of the panel of the controller dies bonded to the panel of sensor structures to form a stacked panel structure at an intermediate stage of packaging in accordance with the packaging process;

FIG. 20 shows a partial side sectional view of the stacked panel structure of FIG. 19 at a subsequent stage of packaging;

FIG. 21 shows a partial side sectional view of the stacked panel structure of FIG. 20 at a subsequent stage of packaging;

FIG. 22 shows a partial side sectional view of the stacked panel structure of FIG. 21 at a subsequent stage of packaging;

FIG. 23 shows a partial side sectional view of the stacked panel structure of FIG. 22 at a subsequent stage of packaging;

FIG. 24 shows a partial side sectional view of the stacked panel structure of FIG. 23 at a subsequent stage of packaging; and

FIG. 25 shows a side sectional view of sensor packages produced from the stacked panel structure of FIG. 24 in accordance with the packaging process of FIG. 5.

### DETAILED DESCRIPTION

Semiconductor packages generally provide a set of related elements. These elements include, in some examples, one or more semiconductor devices to be packaged, interconnection from the devices to the package, a surrounding or containing structure to provide both mechanical support and electrical, chemical, and environmental protection, and a joining structure to attach the package to the board or system. The challenges faced by developers of semiconductor packaging processes result from, for example, the sensitivity of the semiconductor devices (e.g., microelectronics and microstructures) to high temperature processes, the need for suitable shielding, the requirement in some instances for a hermetic or near-hermetic seal to protect the devices from contaminants, and so forth. Due at least in part to these challenges, packaging is one of the major cost drivers for such devices.

One or more of the semiconductor devices in a semiconductor package may be a microelectronic sensor (e.g., a magnetometer), a microelectromechanical systems (MEMS) sensor (e.g., an accelerometer, gyroscope, pressure sensor), or some other miniaturized sensor. With regard to such sensors, proper packaging is important to ensure the integrity of the signals to and from the sensor devices. For example, angular misalignment of a sensor device or multiple sensor devices in a sensor package can lead to inaccuracies in the measured signals. As such, precise angular alignment of sensors in a sensor package is critical for receiving accurate measurements.

Angular alignment of sensors in traditional chip level packaging is currently limited to approximately plus or minus two degrees of accuracy. The angular alignment accuracy is limited by the tolerance of placement equipment utilized in die placement techniques. More precise angular alignment is being called for in the industry to improve the accuracy of measurements received from such sensors. As integrated circuit (IC) device geometries continue to decrease, the use of miniaturized sensor devices continues to rise, and the fabrication of semiconductor packages containing multiple microelectronic components continue to evolve, the need for low cost, accurate, reliable, high density packaging solutions increases.

Embodiments entail sensor packaging methodology and sensor packages produced in accordance with the packaging methodology. The packaging methodology involves a wafer-level packaging technique in lieu of traditional die-to-die placement techniques. Wafer-level packaging refers to packaging semiconductor devices at wafer level, and essentially extends the wafer fabrication process to include device interconnection and device protection processes. The wafer-level packaging process discussed herein provides high-throughput and precise placement packaging of sensors at relatively low cost. Additional advantages entail a chip-scale packaging technology that results in the effective stacking of sensors and microelectronic devices for size reduction, packaging of sensors and microelectronic devices of various sizes, improved electrical performance, and so forth. The subsequent discussion pertains to the packaging of sensors. However, the packaging methodology discussed herein may be implemented to package various types of electronic components.

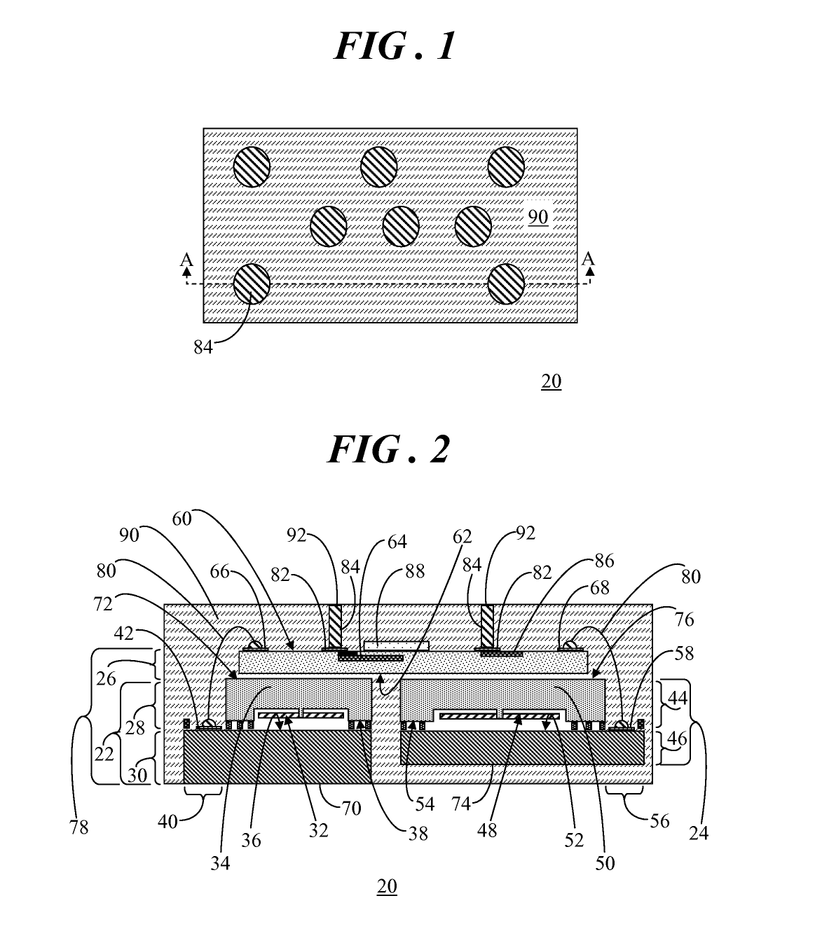

Referring now to FIGS. 1 and 2, FIG. 1 shows a top view of an exemplary sensor package 20 in accordance with an embodiment, and FIG. 2 shows a side view of sensor package 20 along section lines A-A in FIG. 1. In the illustrated embodiment, sensor package 20 includes a first sensor structure 22, a second sensor structure 24, and a semiconductor die, referred to herein as a controller die 26 bonded to first and second sensor structures 22 and 24.

The various FIGS. 1-3 and 5-27 are illustrated using various shading and/or hatching to distinguish the different elements of the sensor packages for clarity of illustration. These different elements may be produced utilizing current and upcoming micromachining techniques. In addition, the terms “first,” “second,” and so forth used herein do not refer to an ordering or prioritization of elements within a countable series of elements. Rather, the terms “first” and “second” are used to distinguish the particular elements for clarity of discussion.

First sensor structure 22 includes a sensor die 28, a cap 30, and a sensor 32 formed on or in a substrate material 34 of sensor die 28. An inner surface 36 of cap 30 is coupled to an inner surface 38 of sensor die 28 with sensor 32 being interposed between sensor die 28 and cap 30. Thus, inner surface 36 of cap 30 is referred to hereinafter as inner cap surface 36 and inner surface 38 of sensor die 28 is referred to hereinafter as inner die surface 38.

Cap 30 generally covers sensor die 28 so as to encapsulate sensor 32. Cap 30 may be attached to sensor die 28, in some embodiments, by a seal ring, so as to seal sensor 32 hermetically or near-hermetically within the encapsulated area. In some embodiments, cap 30 may include a cavity (not shown) extending inwardly from inner cap surface 36 so as to provide clearance for the moving elements of sensor 32, although such a configuration is not a limitation. In the illustrated embodiment shown in FIG. 2, cap 30 includes a substrate portion 40 exposed from sensor die 28. That is, a material section of sensor die 28 does not cover, i.e., is absent from, substrate portion 40 of cap 30. Bond pads 42 are formed on inner cap surface 36 of cap 30 at substrate portion 40. Accordingly, bond pads 42 formed on inner cap surface 36 of cap 30 are located outside the area sealed by cap 30. Bond pads 42 may be electrically connected to various structures and/or electrodes of sensor 32 in accordance with conventional and evolving sensor device manufacturing processes. The electrical interconnections of bond pads 42 with the structures and/or electrodes of sensor 32 are not illustrated or described in detail herein for brevity of discussion.

Likewise, second sensor structure 24 includes a sensor die 44, a cap 46, and a sensor 48 formed on or in a substrate material 50 of sensor die 44. An inner surface 52 of cap 46 is coupled to an inner surface 54 of sensor die 44 with sensor 48 being interposed between sensor die 44 and cap 46. Thus, inner surface 52 of cap 46 is referred to hereinafter as inner cap surface 52 and inner surface 54 of sensor die 44 is referred to hereinafter as inner die surface 54.

Cap 46 generally covers sensor die 44 so as to encapsulate sensor 48. Cap 46 may be attached to sensor die 44, for example, by a seal ring, so as to seal sensor 48 hermetically or near-hermetically within the encapsulated area. In the illustrated embodiment shown in FIG. 2, cap 46 also includes a substrate portion 56 exposed from sensor die 44. That is, a material section of sensor die 44 does not cover, i.e., is absent from, substrate portion 56 of cap 46. Bond pads 58 are formed on inner cap surface 52 of cap 46 at substrate portion 56. Accordingly, bond pads 58 formed on inner cap surface 52 of cap 46 are located outside the area sealed by cap 46. Bond pads 58 may be electrically connected to various structures and/or electrodes of sensor 48 in accordance with conventional and evolving sensor device manufacturing processes. The electrical interconnections of bond pads 58 with the structures and/or electrodes of sensor 48 are not illustrated or described in detail herein for brevity of discussion.

Sensors 32 and 48 may be microelectromechanical systems (MEMS) sensor devices such as accelerometers, gyroscopes, or some other sensors. However, sensors 32 and 48 need not be limited to a MEMS sensor configuration. Rather, sensors 32 and 48 may be optical devices, electro-magnetic devices, chemical devices, or some other electronic devices that contain micron and/or sub-micron sized components. Accordingly, sensors 32 and 48 represent a wide variety of microelectronic and/or micromechanical components for which it is desirable to individually protect, i.e., cap, sensitive features and additionally expose or reveal terminal elements, i.e., the bond pads, at the wafer level. Sensors 32 and 48 are illustrated similarly in FIG. 2 for simplicity of illustration. However, sensors 32 and 48 need not be identical devices, but can instead be any combination of microelectronic and/or micromechanical components best suited for a particular design configuration.

First and second sensor structures 22 and 24, respectively, are shown with their corresponding sensor dies 28 and 44 interposed between their respective caps 30 and 46 and controller die 26. In alternative embodiments, one or both of sensor structures 22 may be arranged in a flipped configuration in which cap 30 and/or cap 46 is interposed between controller die 26 and its corresponding sensor die 28 and/or sensor die 44. In such a design, bond pads 42 and/or 58 may be formed on respective inner die surfaces 38 and/or 54. Additionally, first and second sensor structures 22 and 24, respectively, are shown with only a single sensor 32 or 48 formed on their respective sensor dies 28 and 44. In alternative embodiments, sensor die 28 and/or sensor die 44 may include more than one sensor in accordance with a particular design configuration.

Controller die 26 has a top side 60 and a bottom side 62 opposing top side 60. In FIG. 2, top side 60 is shown as being physically positioned above bottom side 62. Hence, the distinguishing terms “top” and “bottom” are utilized herein. Top side 60 includes control circuitry 64 and bond pads 66 and 68 formed thereon. Control circuitry 64 may be any active or passive circuitry used in the “active area” of controller die 26 for communicating signals to and from sensors 32 and 48, processing data from sensors 32 and 48, communicating with circuitry outside of sensor package 20, and so forth.

First sensor structure 22 includes an outer surface 70 which corresponds to the outer, or external, surface of cap 30. Thus, outer surface 70 is referred to hereinafter as outer cap surface 70 for clarity. First sensor structure 22 further includes an opposing outer surface 72 which corresponds to the outer, or external, surface of sensor die 28. Thus, outer surface 72 is referred to hereinafter as outer die surface 72 for clarity. Likewise, second sensor structure 24 includes an outer surface 74 which corresponds to the outer, or external, surface of cap 46. Thus, outer surface 74 is referred to hereinafter as outer cap surface 74 for clarity. Second sensor structure 24 further includes an opposing outer surface 76 which corresponds to the outer, or external, surface of sensor die 44. Thus, outer surface 76 is referred to hereinafter as outer die surface 76 for clarity. In the illustrated embodiment, bottom side 62 of controller die 26 is generally attached to outer die surface 72 of first sensor structure 22 and to outer die surface 76 of second sensor structure 24 to produce a stacked structure 78.

In first sensor structure 22, bond pads 42 on inner cap surface 36 of substrate portion 40 of cap 30 face in the same direction (i.e., upwardly in FIG. 2) as top side 60 of controller die 26 upon which bond pads 66 are located. Electrical interconnects, referred to herein as bond wires 80, are readily attached between corresponding bond pads 42 on inner cap surface 36 of cap 30 and bond pads 66 on top side 60 of controller die 26 to provide suitable electrical interconnections between controller die 26 and sensor die 28 of first sensor structure 22. Likewise, bond pads 58 of second sensor structure 24 on inner cap surface 52 of substrate portion 56 of cap 46 face in the same direction as top side 60 of controller die 26 upon which bond pads 68 are also located. Bond wires 80 are also attached between corresponding bond pads 58 on inner cap surface 52 of cap 46 and bond pads 68 on top side 60 of controller die 26 to provide suitable electrical interconnections between controller die 26 and sensor die 44 of second sensor structure 24.

Controller die 26 further includes bump pads 82 formed on and distributed across top side 60. In an embodiment, conductive elements 84 are formed on bump pads 82 after controller die 36 is bonded to first and second sensor structures 22 and 24, as discussed in detail below. Conductive elements 84 are illustrated in FIG. 1 as being a circular shape in cross-section. However, conductive elements 84 may have different shapes in cross-section in accordance with particular design criteria. Conductive elements 84 may be pillars, balls, plugs, or some other conductive features that extend above bump pads 82. Conductive elements 84 are utilized as input/output elements for sensor package 20.

In some embodiments, an integral sensor 86 may be formed integrally with the passive and active elements of control circuitry 64 within controller die 26 in accordance with conventional and upcoming semiconductor manufacturing processes. In lieu of or in addition to integral sensor 86, sensor package 20 may include a sensor die 88 mounted on top side 60 of controller die 26. In an embodiment, integral sensor 86 or sensor die 88 may be a magnetometer for measuring the strength or direction of magnetic fields. However, integral sensor 86 and/or sensor die 88 may be some other sensor device in accordance with particular design criteria for sensor package 20.

A packaging material 90 is applied over top side 60 of controller die 26 to encapsulate control circuitry 64, bond wires 80, sensor die 88, and to at least partially encapsulate conductive elements 84 so that only a top surface 92 of conductive elements 84 is exposed from packaging material 90. Packaging material 90 may be any conventional molding compound such as, for example, an epoxy resin material.

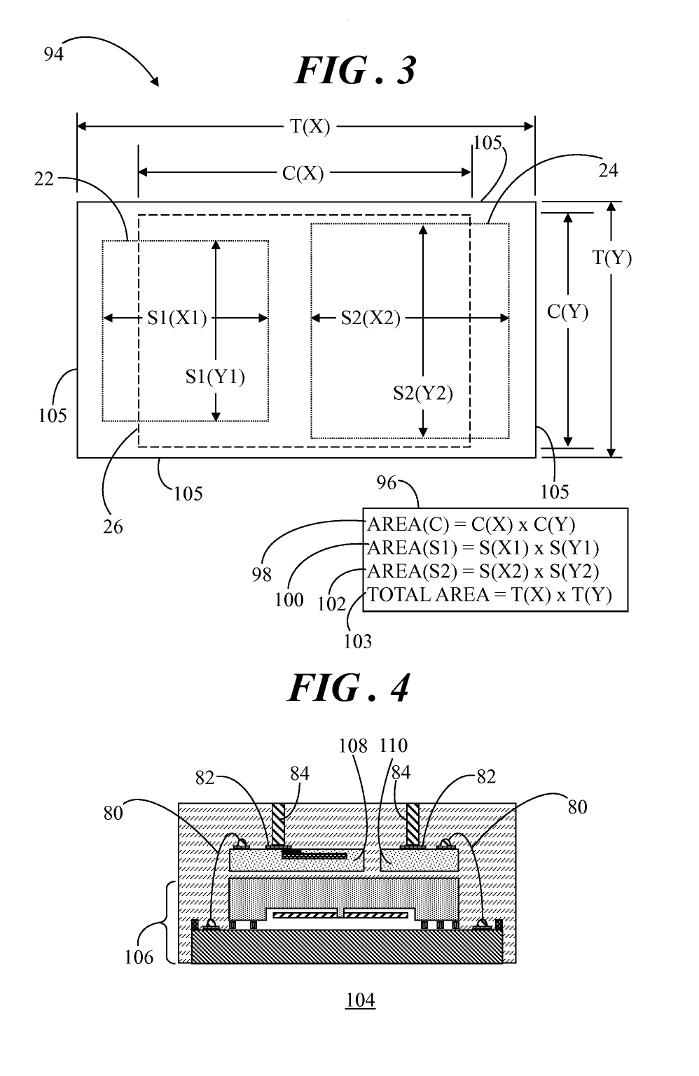

FIG. 3 shows a diagram 94 and associated equations 96 exemplifying various sizes of components within sensor package 20. In the top view diagram 94 of FIG. 3, outlines of first and second sensor structures 22 and 24 are shown in dotted line form and an outline of controller die 26 is shown in dashed line form. In many situations, the X, Y, and Z dimensions of first and second sensor structures 22 and 24 and controller die 26 may vary significantly. The variability of X and Y dimensions is illustrated in FIG. 3 where a surface area 98, labeled AREA(C), of controller die 26 is a product of its length in the X direction, labeled C(X), and its length in the Y direction, labeled C(Y). A surface area 100, labeled AREA(S1), of first sensor structure 22 is a product of its length in the X direction, labeled S(X1), and its length in the Y direction, labeled S(Y1). And, a surface area 102, labeled AREA(S2), of second sensor structure 24 is a product of its length in the X direction, labeled S(X2), and its length in the Y direction, labeled S(Y2).

In this example, surface areas 98, 100, and 102 differ from one another, although surface area 98 of controller die 26 is larger than either of surfaces areas 100 and 102 of first and second sensor structures 22 and 24. Nevertheless, packaging methodology described herein yields a total surface area 103 of sensor package 20 may be larger than surface area 98 and the collective surface areas 100 and 102 of first and second sensor structures 22 and 24. Accordingly, an outer perimeter 105 of sensor package 20 extends slightly beyond the outer perimeters of first and second sensor structures 22 and 24, as well as beyond the outer perimeter of controller die 26. Thus, the dimensions of sensor package 105 are defined by the surface areas 98, 100, and 102 of respective controller die 26, first sensor structure 22, and second sensor structure 24. It should be further noted in the side view of FIG. 2 that the height of each of first and second sensor dies 22 and 24 can also vary in the Z direction relative to one another.

Accordingly, an embodiment described herein entails methodology that cost effectively addresses the problem of a mismatch in surface areas and height between electronic components, such as controller dies and sensor dies for a sensor structure configuration. In particular, the methodology is readily implemented with a wide variety of microelectronic and microelectromechanical systems devices having different dimensional characteristics. As will be discussed in detail below, the methodology entails forming a composite sensor structure that is a combination of first and second sensor structures 22 and 24, respectively, encapsulated in a mold material. The methodology further entails forming a composite controller structure that is a combination of controller die 26 also encapsulated in a mold material. The composite sensor and controller structures are produced to effectively match the footprint of one another so that they can be coupled to form sensor package 20.

FIG. 4 shows a side view of a sensor package 104 in accordance with another embodiment. Sensor package 20 (FIG. 2) is provided to illustrate a configuration in which a sensor package may include two distinct sensor structures that are independently manufactured, and that share the same controller die. However, the configuration of sensor package 20 is not a requirement. Rather, the methodology discussed herein can readily be implemented with a variety of devices, device configurations, devices quantities, and device sizes. By way of example, sensor package 104 includes a single sensor structure 106 coupled to a first controller die 108 and a second controller die 110. First and second controller dies 108 and 110 are electrically interconnected with sensor structure 106 via bond wires 80. Like sensor package 20 (FIG. 2), sensor package 104 additionally includes conductive elements 84 formed on bump pads 82, and sensor package 104 is encapsulated in packaging material 90.

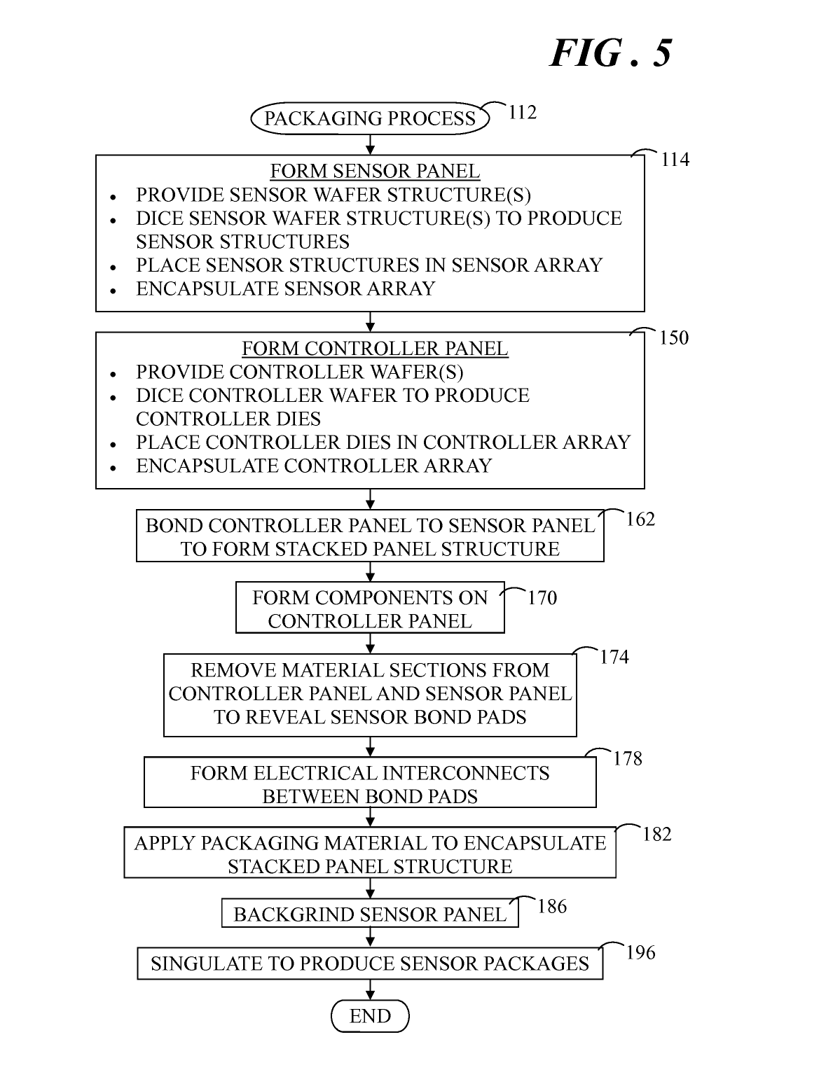

FIG. 5 shows a flowchart of a packaging process 112 for fabricating sensor packages, such as sensor package 20 (FIG. 1), sensor package 104 (FIG. 1), or any of a multiplicity of sensor packages having variable die sizes. Packaging process 112 sets forth a modified wafer-level packaging technique in which semiconductor elements are diced from their original wafers and repackaged into a “new” wafer, referred to herein as a panel, prior to undergoing further wafer-level packaging activities. Packaging process 112 will be discussed in connection with the packaging of a plurality of sensor packages 20 (FIG. 2). However, it should become apparent that the following methodology may be implemented for packaging various types of electronic components. Packaging process 112 sets forth an exemplary flow of operations for clarity of discussion. However, in actual practice there may be variations in the order of operations in accordance with particular processing capabilities of a packaging facility.

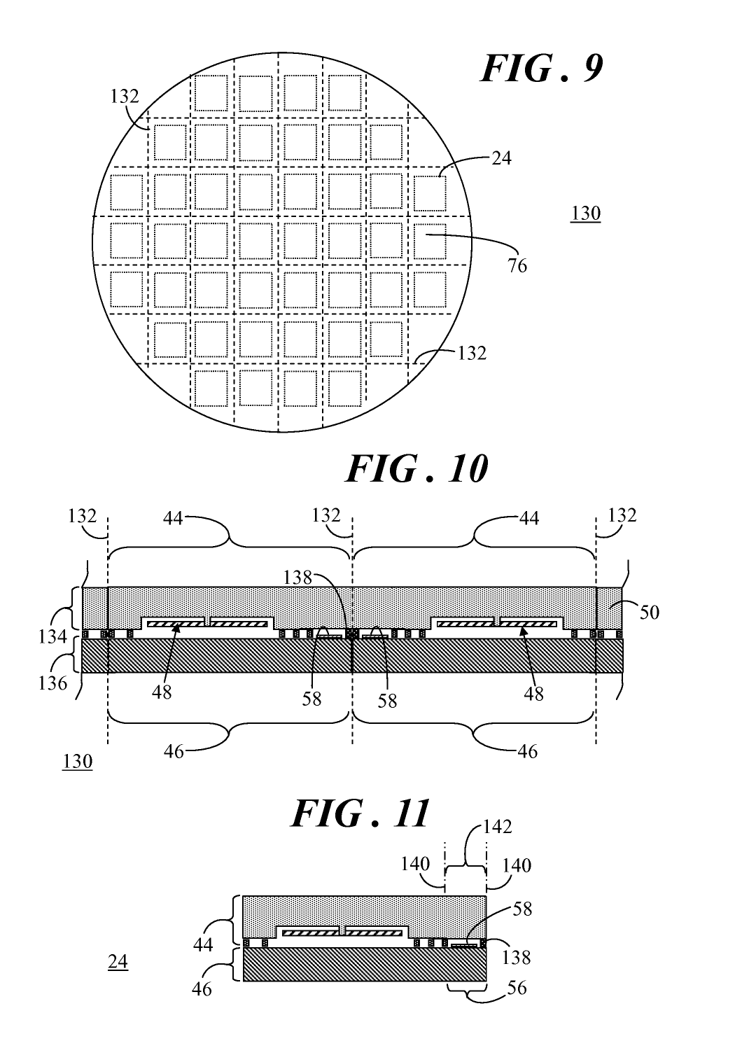

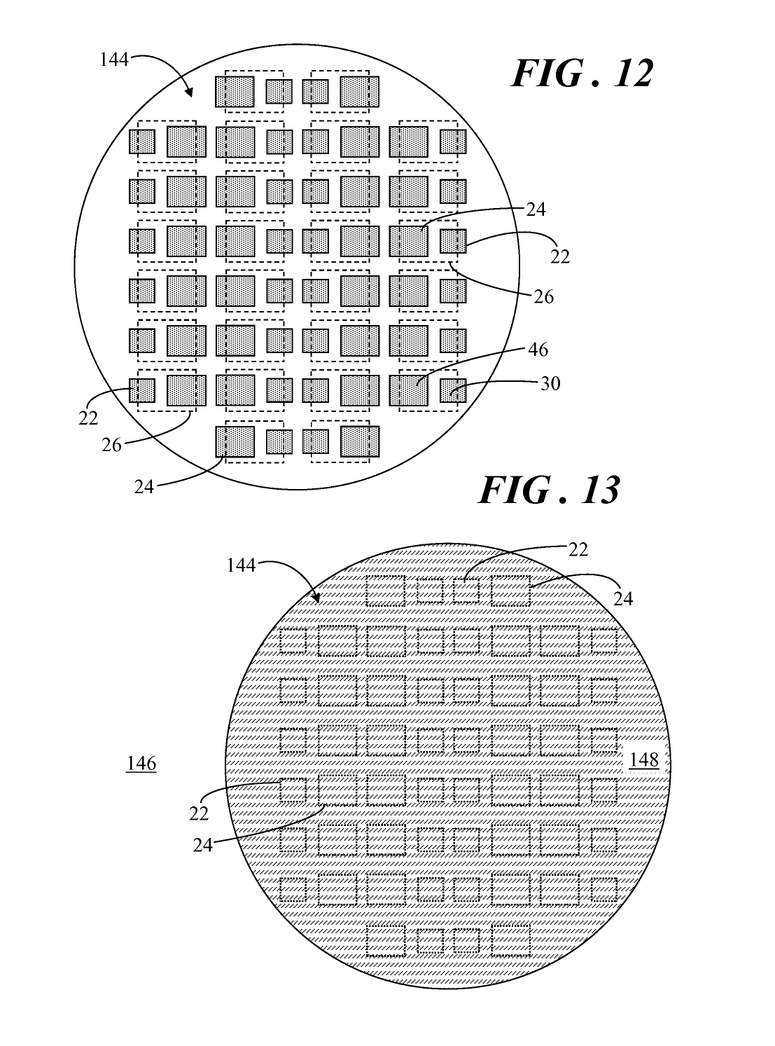

Packaging process 112 begins with an activity 114. At activity 114, a sensor panel is formed. Operations associated with activity 114 entail providing one or more sensor wafer structures, dicing the sensor wafers to produce separate sensor structures, placement of the sensor structures into a sensor array, and encapsulating the sensor array to form the sensor panel. Details regarding activity 114 are discussed in connection with FIGS. 6-13. In particular, FIGS. 6-8 illustrate the provision and dicing of a sensor wafer structure to produce first sensor structures 22 (FIG. 2). FIGS. 9-11 illustrate the provision and dicing of a sensor wafer structure to produce second sensor structures 24 (FIG. 2). FIG. 12 illustrates the placement of first and second structures into a sensor array, and FIG. 13 illustrates the encapsulation of the sensor array to form the sensor panel.

Now referring to FIG. 6, FIG. 6 shows a top view of a sensor wafer structure 116 used in connection with packaging process 112 (FIG. 5). FIG. 6 particularly illustrates an exemplary sensor wafer structure 116 which includes a plurality of first sensor structures 22, represented by dotted lines, used to produce stacked structure 78 (FIG. 2) of sensor package 20 (FIG. 2). Thus, in the top view of sensor wafer structure 116, outer die surface 72 of sensor die 28 (FIG. 2) is visible.

Sensor wafer structure 116 may be manufactured utilizing conventional and upcoming bulk micromachining, surface micromachining, and/or high aspect ratio silicon micromachining techniques. Fabrication processes for a surface micromachining technique can generally include, for example, deposition, patterning, and etching of one or more sacrificial oxide layers, one or more structural polysilicon layers, and the like. For example, one or more sacrificial oxide layers may be deposited overlying the silicon-based wafer, and one or more structural layers may then be deposited over the sacrificial layers.

All elements in sensor wafer structures 116 may be identical or sensor wafer structure 116 can contain a mixture of sensor elements. Dashed lines 118 represent borders delineating the various first sensor structures 22 that make up sensor wafer structure 116. Dashed lines 118 can additionally represent the locations at which sensor wafer structure 116 may eventually be sawn, diced, etched, or otherwise singulated in one or more separate operations (discussed below). Thus, dashed lines 118 are referred to hereinafter as saw lines 118.

Sensor wafer structure 116 is illustrated as being generally disk-shaped. However, alternative embodiments of sensor wafer structure 116 may be any suitable shape, such as rectangular shaped. The quantity of first sensor structures 22 that make up a given sensor wafer structure 116 varies depending upon the size of first sensor structures 22 and upon the size of the wafers (discussed below) used to assemble sensor wafer structure 116.

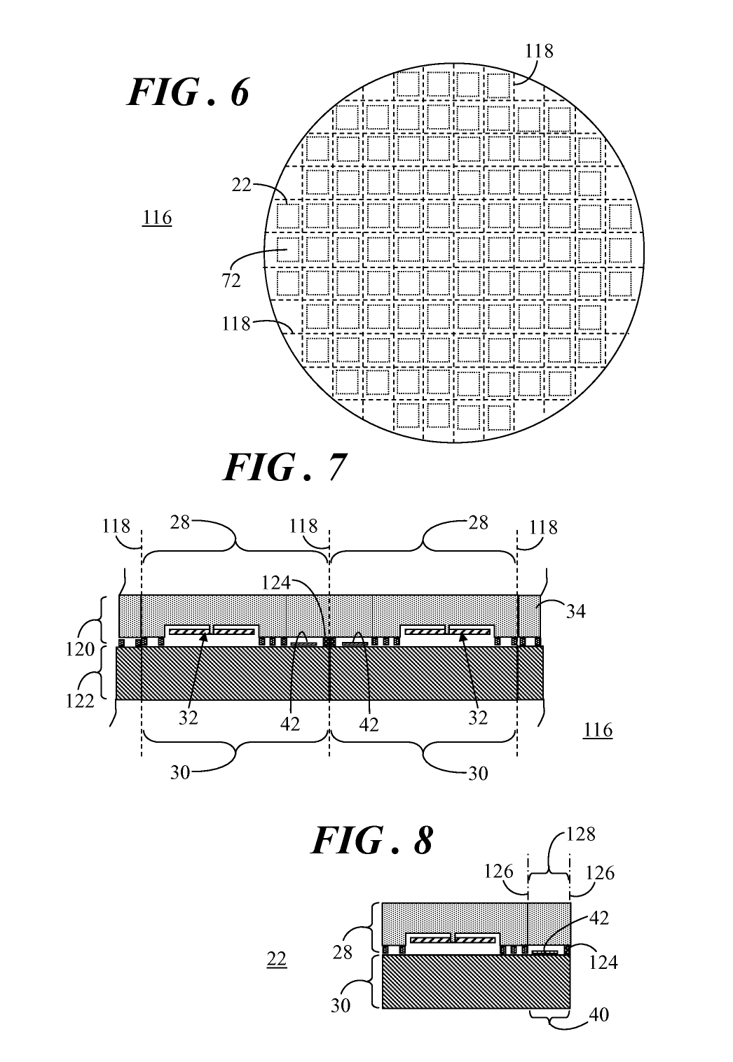

FIG. 7 shows a partial side view of sensor wafer structure 116. Sensor wafer structure 116 includes a sensor wafer 120, a cap wafer 122, and a plurality of sensors 32 formed on substrate material 34 of sensor wafer 120. In accordance with conventional and upcoming processes, sensor wafer 120 is fabricated to include sensors 32 and cap wafer 122 is separately fabricated. Cap wafer 122 is subsequently coupled to sensor wafer 120 using any suitable bonding technique and bonding material. Saw lines 118 are shown delineating the boundaries of each adjacent sensor die 28. Likewise, saw lines 118 are shown delineating the boundaries of each adjacent cap 30.

In accordance with an embodiment, sensor wafer structure 116 includes seal members 124 extending between sensor wafer 120 and cap wafer 122. Seal members 124, of which only one is visible, are positioned between bond pads 42 and saw lines 118. In an embodiment, seal members 124 bridge saw lines 118 between adjacent pairs of bond pads 42. As such, seal members 124 are wider than the dicing width of the equipment used to dice sensor wafer structure 116 along saw lines 118. The inclusion of seal members 124 shields bond pads 42 from contaminants when sensor wafer structure 116 is diced along saw lines 118.

FIG. 8 shows a side view of one of first sensor structures 22 produced following dicing of the sensor wafer structure 116 in accordance with activity 114 (FIG. 5) of packaging process 112 (FIG. 5). At activity 114, the provided sensor wafer structure 116 is diced or sawn along saw lines 118 (FIG. 7) to produce first sensor structures 22. That is, singulated first sensor structures 22, each of which includes one of sensor dies 28, is produced. The singulated first sensor structures 22 will be implemented as sensor elements to form a “new” wafer, i.e., a sensor panel (discussed below).

As mentioned previously, sensor wafer structure 116 (FIG. 7) includes seal members 124. Seal members 124 are advantageous in configurations in which singulated first sensor structures 22 are to be utilized to form a sensor panel (discussed below). Since seal members 124 bridge saw lines 118 (i.e., are wider than the width of the cut), a portion of each of seal members 124 remains in place extending between sensor die 28 and cap 30 when sensor wafer structure 116 is diced. This remaining portion of seal members 124 largely shields bond pads 42 from contaminants during the dicing operation and other ensuing activities.

In the illustrated embodiment, lines 126 denoted by a dash-dot sequence represent the locations at which a material portion (discussed below) of first sensor structure 22 will be removed in order to access bond pads 42 of cap 30. These lines 126 are referred to hereinafter as saw-to-reveal lines 126. Therefore, the pair of saw-to-reveal lines 126 delineates a material section 128 of each controller die 28 to be removed in accordance with packaging process 112 (FIG. 5) to expose the underlying bond pads 42 formed on substrate portion 40 of cap 30.

Now referring to FIGS. 9-11, FIG. 9 shows a top view of a sensor wafer structure 130 used in connection with packaging process 112 (FIG. 5). FIG. 9 particularly illustrates an exemplary sensor wafer structure 130 which includes a plurality of second sensor structures 24, represented by dotted lines, used to produce stacked structure 78 (FIG. 2) of sensor package 20 (FIG. 2). Thus, in the top view of sensor wafer structure 130, outer die surface 76 of sensor die 44 (FIG. 2) is visible. Sensor wafer structure 130 may be manufactured utilizing conventional and upcoming bulk micromachining, surface micromachining, and/or high aspect ratio silicon micromachining techniques.

Dashed lines 132 represent borders delineating the various second sensor structures 24 that make up sensor wafer structure 130. Dashed lines 132 can additionally represent the locations at which sensor wafer structure 130 may eventually be sawn, diced, etched, or otherwise singulated in one or more separate operations. Thus, dashed lines 132 are referred to hereinafter as saw lines 132. Sensor wafer structure 130 is illustrated as being generally disk-shaped. However, alternative embodiments of sensor wafer structure 130 may be any suitable shape, such as rectangular shaped. The quantity of second sensor structures 24 that make up a given sensor wafer structure 130 varies depending upon the size of second sensor structures 24 and upon the size of the wafers (discussed below) used to assemble sensor wafer structure 130.

FIG. 10 shows a partial side view of sensor wafer structure 130. Sensor wafer structure 130 includes a sensor wafer 134, a cap wafer 136, and a plurality of sensors 48 formed on substrate material 50 of sensor wafer 134. In accordance with conventional and upcoming processes, sensor wafer 134 is fabricated to include sensors 48 and cap wafer 136 is separately fabricated. Cap wafer 136 is subsequently coupled to sensor wafer 134 using any suitable bonding technique and bonding material. Saw lines 132 are shown delineating the boundaries of each adjacent sensor die 44. Likewise, saw lines 132 are shown delineating the boundaries of each adjacent cap 46.

In accordance with an embodiment, sensor wafer structure 130 also includes seal members 138 extending between sensor wafer 134 and cap wafer 136. Seal members 138 are positioned between bond pads 58 and saw lines 132. In an embodiment, seal members 138 bridge saw lines 132 between adjacent pairs of bond pads 58. As such, seal members 138 are wider than the dicing width of the equipment used to dice sensor wafer structure 130 along saw lines 132 so as to shield bond pads 58 from contaminants when sensor wafer structure 130 is diced along saw lines 132.

FIG. 11 shows a side view of one of second sensor structures 24 produced following dicing of the sensor wafer structure 130 in accordance with activity 114 (FIG. 5) of packaging process 112 (FIG. 5). At activity 114, the provided sensor wafer structure 130 is diced or sawn along saw lines 132 (FIG. 9) to produce second sensor structures 24. That is, singulated second sensor structures 24, each of which includes one of sensor dies 44, is produced. Since seal members 138 bridge saw lines 132 (i.e., are wider than the width of the cut), a portion of each of seal members 138 remains in place extending between sensor die 44 and cap 46 when sensor wafer structure 130 is diced to shield bond pads 58.

In the illustrated embodiment, lines 140 denoted by a dash-dot sequence represent the locations at which a material section 142 of second sensor structure 24 will be removed in order to access bond pads 58 formed on substrate portion 56 of cap 46. These lines 140 are referred to hereinafter as saw-to-reveal lines 140.

FIG. 12 shows a top view of a sensor array 144 of first and second sensor structures 22 and 24, respectively, used in connection with activity 114 (FIG. 5) of packaging process 112 (FIG. 5). As will be discussed below, controller dies 26 (FIG. 2) are arranged in a corresponding controller array to form a controller panel. Thus, first and second sensor structures 22 and 24 in sensor array 144 are arranged to correspond with locations of controller dies in its associated controller array.

For illustrative purposes, controller dies 26 are shown in dotted line form with first and second sensor structures 22 and 24 in order to correlate the alignment of sensor structures 22 and 24 in sensor array 144 with the locations of controller dies 26 in its controller array. First and second sensor structures 22 and 24 are thus distributed in sensor array 144 to align with controller dies 26. First and second sensor structures 22 and 24 may be picked and placed in a wafer format on pitches which correspond to the pitch of controller dies 26.

Sensor array 144 includes four columns of pairs of first and second sensor structures 22 and 24 in this exemplary configuration. However, any quantity of first and second sensor structures 22 and 24 may be present in sensor array 144 in accordance with the quantity of controller dies 26 in its corresponding controller array. In this illustration, first and second sensor structures 22 and 24 are oriented with caps 30 and 46 facing upwardly. However, in alternative arrangements, first and second sensor structures 22 and 24 may be oriented in reverse so sensor dies 28 and 44 (FIG. 2) would be visible.

FIG. 13 shows a top view of a sensor panel 146 of first and second sensor structures 22 and 24 produced in accordance with activity 114 (FIG. 5) of packaging process 112 (FIG. 5). In particular, a mold material 148 is deposited over first and second sensor structures 22 and 24 (shown in dashed line form) of sensor array 144 to form a new sensor “wafer”, i.e., sensor panel 146, whose size and arrangement of first and second sensor structures 22 matches controller dies 26 (FIG. 2) of a controller panel (discussed below) that will be formed in accordance with packaging process 112. Thus, sensor panel 146 is a composite panel structure that includes multiple paired first and second sensor structures 22 and 24 encapsulated by mold material 148. The placement and encapsulation operations of activity 114 of packaging process 112 yield excellent accuracy for the rotation angles of sensor dies 28 and 44 (FIG. 2) in first and second sensor structures 22 and 24 of sensor array 144.

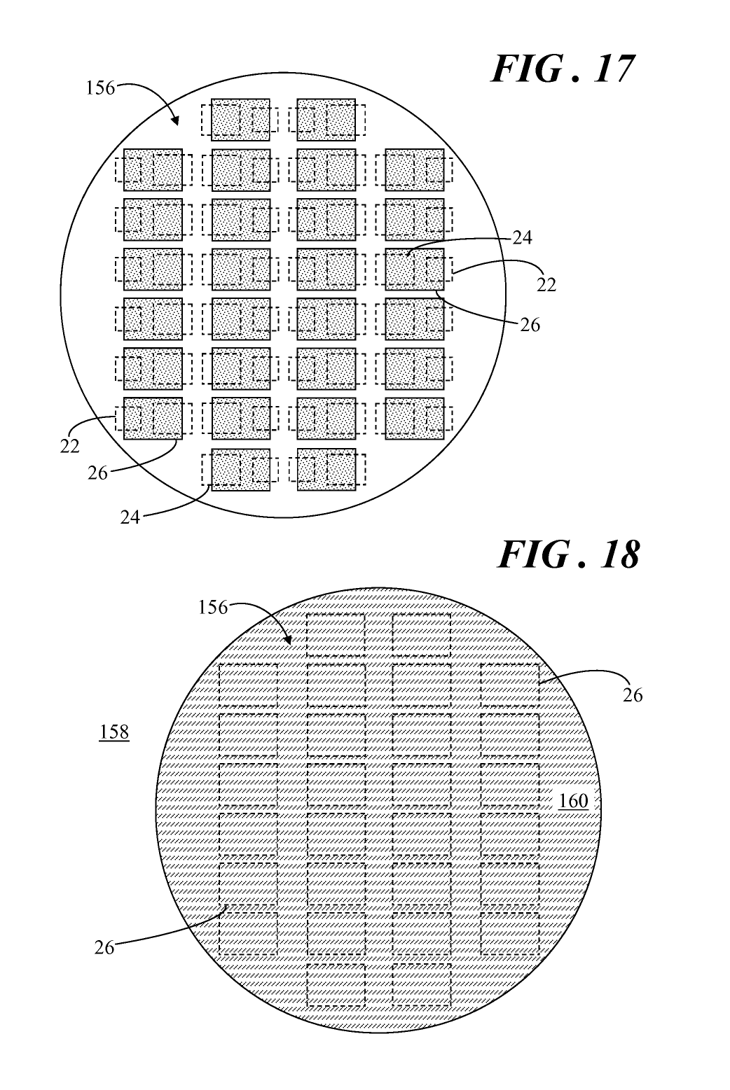

With reference back to packaging process 112, an activity 150 is performed in cooperation with activity 114. At activity 150, a controller panel is formed. Operations associated with activity 150 entail providing one or more controller wafers, dicing the controller wafers to produce separate controller dies 26 (FIG. 2), placement of controller dies 26 into a controller array, and encapsulating the controller array to form the controller panel. Details regarding activity 150 are discussed in connection with FIGS. 14-18. In particular, FIGS. 14-16 illustrate the provision and dicing of a controller wafer to produce controller dies 26 (FIG. 2). FIG. 17 illustrates the placement of controller dies 26 into a controller array, and FIG. 18 illustrates the encapsulation of the controller array to form the controller panel.

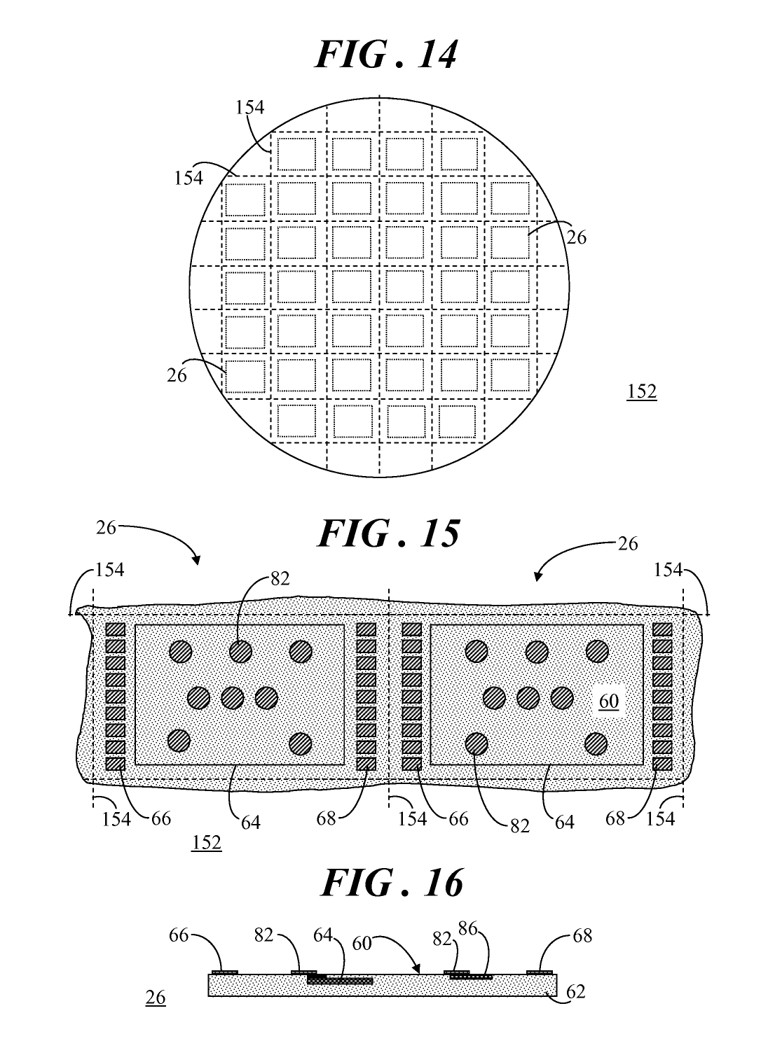

Now referring to FIGS. 14-16, FIG. 14 shows a top view of a controller wafer 152 used in connection with activity 150 of packaging process 112. FIG. 15 shows an enlarged partial top view of controller wafer 152, and FIG. 16 shows side view of one of controller dies 26 produced following dicing of controller wafer 152. Controller wafer 152 has top side 60 and bottom side 62, in which top side 60 includes a plurality of controller dies 26, and each of controller dies 26 includes control circuitry 64 and, in some embodiments, integral sensor 86.

Controller wafer 152 may be manufactured utilizing conventional and upcoming integrated circuit (IC) fabrication techniques for forming control circuitry 64 in the active regions of controller wafer 152. The implementation of standard IC wafer fabrication techniques creates transistors, capacitors, resistors, diodes, and all other components of control circuitry 64 and, if present, integral sensor 86. In addition, these IC fabrication techniques may be implemented to form bond pads 66 and 68, and bumps pads 82 at top side 60 of controller wafer 52. These conventional process steps need not be described herein.

Top side 60 of controller wafer 152 is marked with dashed lines 154 along the generally planar top side 60 of controller wafer 152. Dashed lines 154 represent the locations at which controller wafer 152 will be sawn or diced to produce singulated controller dies 26. Dashed lines 154 are collectively referred to herein as saw lines 154. As such, the provided controller wafer 152 is diced or sawn along saw lines 154 to produce controller dies 26, at activity 150 (FIG. 5). Controller wafer 152 is illustrated as being generally disk-shaped. However, alternative embodiments of controller wafer 152 may be any suitable shape, such as rectangular shaped. Additionally, the quantity of controller dies 26 formed on a given controller wafer 152 varies depending upon the size of controller dies 26 and upon the size of controller wafer 152.

Now referring to FIG. 17, FIG. 17 shows a top view of a controller array 156 of controller dies 26 produced in connection with activity 150 (FIG. 5) of packaging process 112 (FIG. 5). As discussed above, first and second sensor structures 22 and 24, respectively, are arranged in the corresponding sensor array 144 (FIG. 12) to form sensor panel 146 (FIG. 13). Likewise, controller dies 26 (FIG. 2) are also arranged in the corresponding controller array 156 to form a controller panel (discussed below). Thus, controller dies 26 in controller array 156 are positioned to correspond with the locations of first and second sensor structures 22 and 24 in sensor array 144.

For illustrative purposes, first and second sensor structures 22 and 24 are shown in dotted line form with controller dies 26 in order to correlate the alignment of controller dies 26 with first and second sensor structures 22 and 24 in sensor array 144. Controller dies 26 are thus distributed in controller array 156 to align with first and second sensor structures 22 and 24 in sensor array. Controller dies 26 may be picked and placed in a wafer format on pitches which correspond to the pitches of the first and second sensor structures 22 and 24. Controller array 156 includes four columns of controller dies 26 in this exemplary configuration. However, any quantity of controller dies 26 may be present in controller array 156 in accordance with the quantity of first and second sensor structures 22 and 24 in its corresponding sensor array 144.

FIG. 18 shows a top view of a controller panel 158 of controller dies 26 produced in accordance with activity 150 (FIG. 5) of packaging process 112 (FIG. 5). In particular, a mold material 160 is deposited over controller dies 26 (shown in dashed line form) of controller array 156 to form a new controller “wafer”, i.e., controller panel 158, whose size and arrangement of controller dies 26 matches first and second sensor structures 22 and 24 (FIG. 2) of sensor panel 146 (FIG. 13). Thus, controller panel 158 is a composite panel structure that includes multiple controller dies 26 encapsulated by mold material 160. The placement and encapsulation operations of activity 150 of packaging process 112 yield excellent accuracy for the rotation angles of controller dies 26 of controller array 156.

Returning back to packaging process 112 (FIG. 5), following activities 114 and 150, processing continues with an activity 162. At activity 162, controller panel 158 (FIG. 18) is bonded to sensor panel 146 (FIG. 13) to form a stacked panel structure.

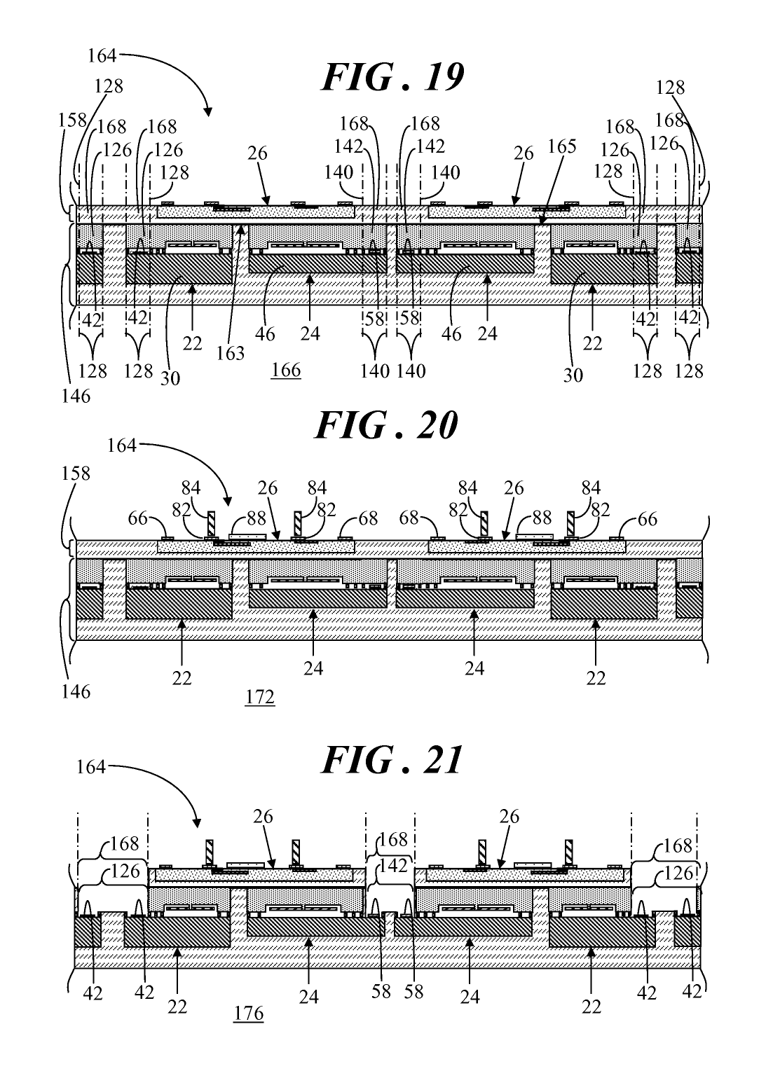

With reference to FIG. 19 in connection with activity 162, FIG. 19 shows a partial side sectional view of controller panel 158 bonded to sensor panel 146 to form a stacked panel structure 164 at an intermediate stage 166 of packaging. In some embodiments, it may be useful to backgrind controller panel 158 prior to bonding it to sensor panel 146. Following a backgrinding process, bonding may be performed utilizing direct bonding, adhesive bonding, thermocompression bonding, reactive bonding, plasma activated bonding, anodic bonding, eutectic bonding, or any other suitable bonding technique. For example, an epoxy die attach material or film may be utilized to bond a bottom surface 163 of controller panel 158 to a top surface 165 sensor panel 146. As shown in FIG. 19, material sections 168 of controller panel 158 and material sections 126 and 141 of first and second sensor structures 22 and 24, respectively, delineated by saw-to-reveal lines 128 and 140 conceal the underlying bond pads 42 and 58 formed on caps 30 and 46, respectively.

Alignment of controller dies 26 of controller panel 158 with first and second sensor structures 22 and 24 of sensor panel 146 may be achieved by utilizing mechanical or optical fiduciary marks, such as notches at the edges of controller panel 158 and sensor panel 146, pins, etchings, or holographic images, among others. Automatic process equipment for wafer bonding, as well as the integration of suitable alignment techniques, can provide precision location keyed to specific features on the semiconductor elements within panels 146 and 158. Thus, angular alignment of less than one tenth of a degree of accuracy for the sensors may be achieved. This alignment accuracy is in contrast with the angular alignment of sensors achieved in traditional chip level die packaging, which is typically limited to approximately plus or minus two degrees of accuracy.

Referring back to FIG. 5, packaging process 112 continues with an activity 170 following bonding activity 162. At activity 170, components may be formed on or attached to controller dies 26 of controller panel 158. These components can include, for example, conductive elements 84 (FIG. 2) on bump pads 82 (FIG. 2) of controller dies 26 (FIG. 2) and sensor die 88 (FIG. 2), when the design configuration of sensor package 20 (FIG. 2) calls for sensor die 88.

Referring now to FIG. 20 in connection with activity 170, FIG. 20 shows a partial side sectional view of stacked panel structure 164 of FIG. 19 at a subsequent stage 172 of packaging. As shown in FIG. 120, conductive elements 84 are formed on bump pads 84 of controller dies 26 in controller panel 156. Conductive elements 84 may be copper pillars that are plated onto bump pads 82 of controller dies 26. Alternatively, stud bumps or solder balls may be attached to bump pads 82 in accordance with conventional processes.

Conductive elements 84 are formed on bump pads 82 of the bonded panels of stacked panel structure 164 as a wafer-level process to achieve improvements in rotational accuracy of sensor package 20 (FIG. 2) to the product circuit. Formation of conductive elements 84 as a wafer-level process achieves accuracy improvements as compared with assembling a die into a sensor package, followed by assembling the sensor package into a product circuit. Accordingly, when sensor package 20 is eventually assembled to a product circuit by, for example, soldering, the location and rotation of sensor package 20 relative to the product circuit will be determined by the location and rotation of conductive elements 84 because the solder will align conductive elements 84 to the corresponding features on the product circuit. As mentioned above, there may be variations in the order of operations in accordance with particular processing capabilities of a packaging facility. For example, conductive elements 84 may be formed at different stages of packaging process 112, for example, after wirebonding or after encapsulation, but prior to a singulation activity (discussed below).

As further shown in FIG. 20, sensor dies 88 may be bonded to controller dies 26 of controller panel 156 by a die attach process and wire bonded to controller dies 26. Alternatively, sensor dies 88 may be mounted to controller dies 26 utilizing a flip chip technique in which sensor dies 88 are inverted and connected directly to controller dies 26 within controller panel 156 using, for example, solder bump mounting, stud bump bonding, and the like, rather than a conventional wire bonding technique. The mounting of sensor dies 88 onto controller dies 26 of controller panel 156 can achieve improved package density.

With reference back to FIG. 5, following activity 170, packaging process 90 continues with an activity 174. At activity 174, material sections 168 of controller panel 158 and material sections 126 and 142 of sensor panel 146 that are coincident, i.e., in stacked arrangement, with material sections 168 are removed to reveal bond pads 42 on caps 30 and bond pads 58 on caps 46 (see FIG. 2).

Referring to FIG. 21 in connection with activity 174, FIG. 21 shows a partial side sectional view of stacked panel structure 164 at a subsequent stage 176 of packaging. As shown in FIG. 21, material sections 168 of controller panel 158 and material sections 126 and 142 of sensor panel 146 have been removed to expose, i.e., reveal, bond pads 42 and 58, of the underlying caps 30 and 46. Material sections 168, 126, and 142 may be removed by sawing along saw-to-reveal lines 128 and 140 in stacked panel structure 164, first shown in FIGS. 8 and 11 and repeated in FIG. 19.

Again referring back to FIG. 5, once material sections 168, 126, and 142 have been removed to expose, i.e., reveal, bond pads 42 and 58 at activity 174, packaging process 112 continues with an activity 178. At activity 178, electrical interconnects in the form of bond wires 80 are attached between bond pads 42 of caps 30 and bond pads 66 of controller dies 26. Likewise, bond wires 80 are attached between bond pads 58 of caps 46 and bond pads 68 of controller dies 26 within controller panel 158.

Referring now to FIG. 22 in connection with activity 178, FIG. 22 shows a partial side sectional view of stacked panel structure 164 at a subsequent stage 180 of packaging. As shown, bond wires 80 are bonded to bond pads 42 of caps 30 and to corresponding bond pads 66 on top side 60 of controller dies 26 using a conventional wire bonding process. Likewise, bond wires 80 are bonded to bond pads 58 of caps 46 and to corresponding bond pads 68 on top side 60 of controller dies 26 using a conventional wire bonding process. It should be observed that conductive elements 84 are higher than the wire bond loop height of bond wires 80. Wire bonding is a cost-effective and flexible interconnect technique, and can be readily implemented when forming electrical interconnects during a wafer-level fabrication process.

Referring back to FIG. 5, following wire bonding activity 178, packaging process 112 continues with an activity 182. At activity 182, packaging material 90 (FIG. 2) is applied to encapsulate stacked panel structure 164.

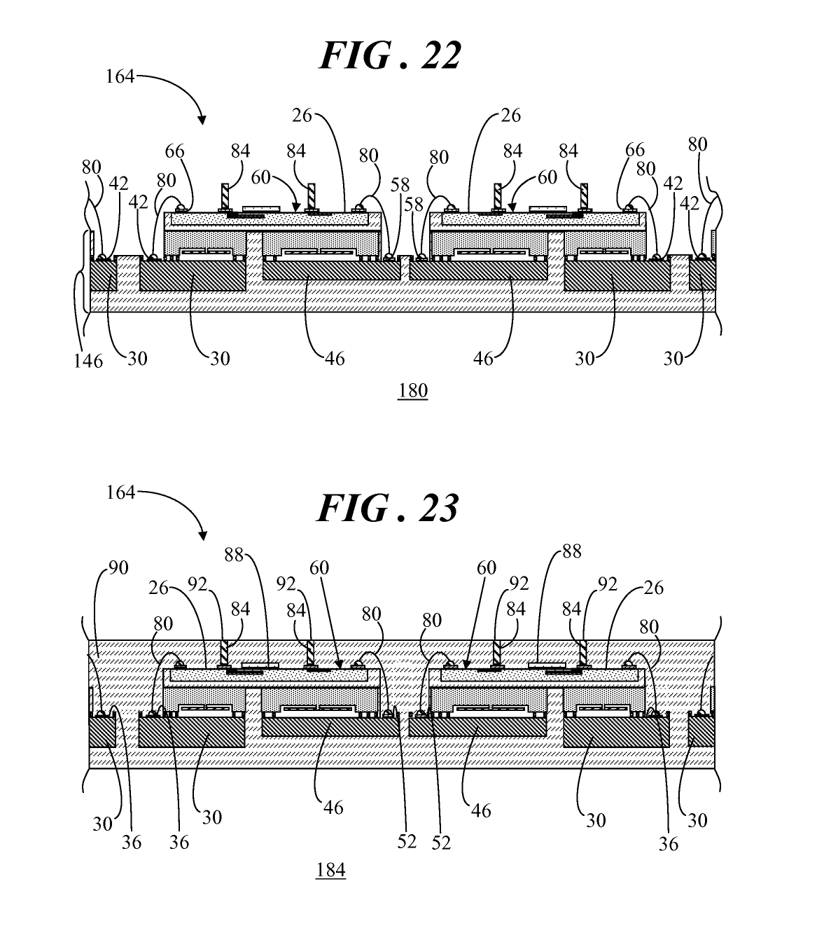

With reference to FIG. 23 in connection with activity 182, FIG. 23 shows a partial side sectional view of stacked panel structure 164 at a subsequent stage 184 of packaging. As shown in FIG. 23, conductive elements 84, top side 60 of controller dies 26, sensor die 88, bond wires 80, and exposed inner cap surfaces 36 and 52 of caps 30 and 46, respectively, are encapsulated with packaging material 90. Packaging material 90 may be mold compound, potting compound, epoxy resin, and so forth. Packaging material 90 is applied in a thick enough layer to cover bond wires 80 and conductive elements 84. However, if packaging material 90 entirely covers conductive elements 84 during encapsulation, packaging material 90 may be ground down or otherwise abraded to expose top surface 92 of conductive elements 84 without exposing bond wires 80.

Referring back to FIG. 5, following activity 182, packaging process 112 continues with a task 186. At task 186, sensor panel 146 undergoes a backgrinding process using a conventional abrasive material and equipment to thin sensor panel 144.

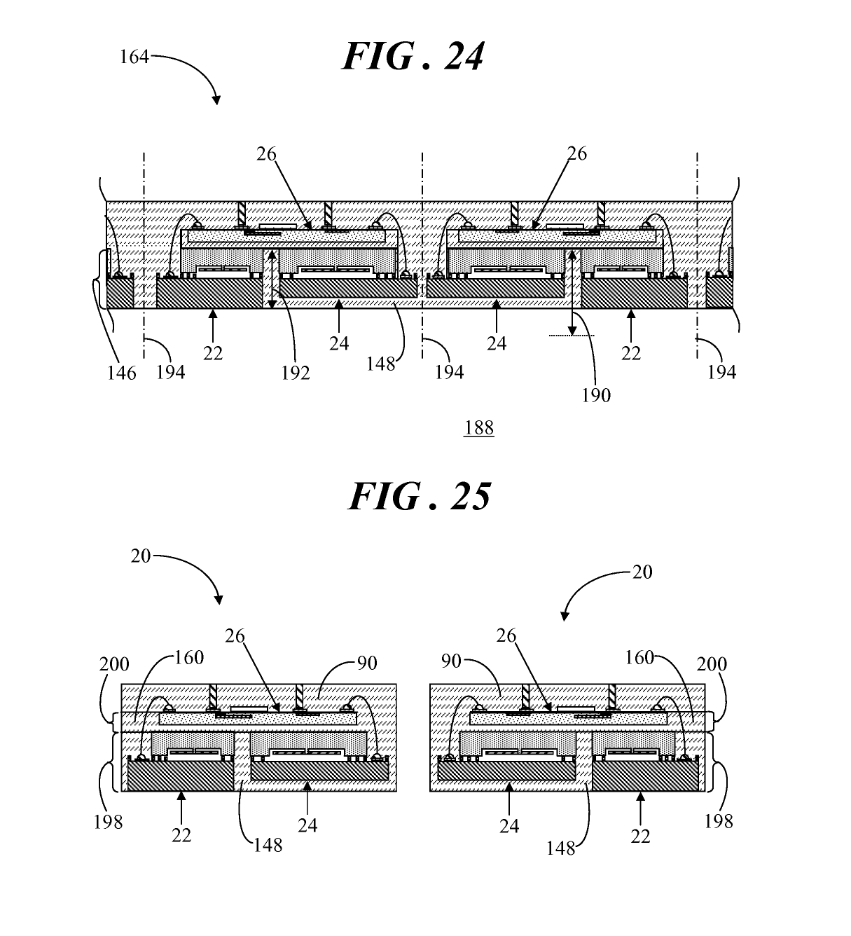

With reference now to FIG. 24, FIG. 24 shows a partial side sectional view of stacked panel structure 164 of FIG. 20 at a subsequent stage 188 of packaging. As represented in FIG. 24 by a dotted line, sensor panel 146 may exhibit an initial thickness 190 following encapsulation within activity 114 (FIG. 5). Wafer backgrinding is a semiconductor device fabrication operation in which wafer thickness is reduced to enable stacking and high density packaging of semiconductor devices. Wafer backgrinding removes excess mold material 148 from an underside of sensor panel 144 so that a final thickness 192 of sensor panel 144 following execution of backgrinding activity 186 is less than initial thickness 190. Final thickness 192 can be any suitable dimension that is as thin as possible without unduly sacrificing mechanical stability of sensor panel 144 and/or damaging first and second sensor structures 22 and 24. Note that for illustrative purposes, stacked panel structure 164 is shown with saw lines 194 indicating where stacked panel structure 164 will eventually be diced to produce sensor packages 20 (FIG. 2).

Again referring back to FIG. 5, following any of wire bonding activity 178, encapsulation activity 182, and/or backgrinding activity 186, continued processing may be performed which is not shown herein for brevity. This continued processing may entail the addition of solder balls above conductive elements 84. The added solder balls can increase standoff and improve the electrical interconnection Additional continued processing may entail visual inspection, operational testing, burn-in, stress testing, accelerated life testing, the build-up of additional redistribution layers above packaging material 90 and top surface 92 of conductive elements 84, and so forth all while still at wafer level.

Following activity 186, an activity 196 is eventually performed. At activity 196, the fabricated stacked panel structure 164 is singulated, i.e., cut, punched, or diced, in a conventional manner. Following activity 196, packaging process 112 ends.

Referring to FIG. 25 in connection with activity 196, FIG. 25 shows a side sectional view of sensor packages 20 produced from stacked panel structure 164 (FIG. 24) in accordance with packaging process 112. As shown, stacked panel structure 164 has been singulated, i.e., cut, punched, or diced, along saw lines 194 (FIG. 24). Following singulating activity 196, the individual sensor packages 20 can be coupled onto, for example, a printed circuit board in an end application.

Each of the resulting sensor packages 20 represents a chip-scale package in which the X and Y package dimensions of each sensor package 20 are driven by the X and Y dimensions of the largest components or the largest grouping of components in one of the panels, and their locations relative to one another. In this exemplary scenario, following dicing activity 196, a composite sensor structure 198 is produced that includes first and second sensor structures 22 and 24, respectively, encapsulated by mold material 148. Encapsulation of first and second sensor structures 22 and 24 yields composite sensor structure 198 having total surface area 103 (FIG. 3) in the X and Y dimensions that is larger than the individual surface area 100 (FIG. 3) and surface area 102 (FIG. 3) for each of first and second sensor structures 22 and 24. Additionally, a composite controller structure 200 is produced that includes controller die 26 encapsulated by mold material 160. Encapsulation of controller die 26 yields composite controller structure 200 that is larger than surface area 98 of controller die 26. Particularly, composite controller structure 200 also exhibits total surface area 103, i.e., the same footprint as composite sensor structure 198.

Embodiments described herein entail sensor packaging methodology and sensor packages produced in accordance with the packaging methodology. The packaging methodology involves a wafer-level packaging technique in lieu of traditional die placement techniques. In accordance with the wafer-level packaging technique, one or more sensor wafer structures are diced into singulated sensor structures, without exposing bond pads to contamination. The singulated sensor structures are picked and placed into an array and encapsulated to form a sensor panel. Likewise, a one or more controller wafers are diced into controller dies, which are picked and placed into an array and encapsulated to form a controller panel. The controller panel is subsequently bonded to the sensor panel to form a stacked panel structure with the active side of the controller dies facing outwardly from the package. Thus, the package inputs and outputs can be formed on the controller dies while the controller dies are in wafer form, i.e., in controller panel. A portion of the stacked panel structure is sawn, etched, or otherwise cut to reveal the underlying bond pads within the sensor panel structure. The corresponding bond pads for the controller dies in the controller panel are wire bonded to the sensor bond pads in wafer format. The methodology is particularly useful when the electronic components, such as controller dies and sensor structures, are a variety of sizes, shapes, and quantities for particular sensor packages.

The wafer-level packaging process is especially suitable for the packaging of miniaturized sensors where precise rotation and tilt accuracy of the sensors can be achieved at the wafer level, rather than at the die level. Moreover, the required angular accuracy can be assured without more costly and time consuming testing. Accordingly, the wafer-level packaging process discussed herein provides high-throughput and precise placement packaging of sensors at relatively low cost. Moreover, the wafer-level packaging process results in individual sensor packages that are generally the same size as the largest component or collective components in a panel, effective stacking of sensors and microelectronic devices for size reduction and improved package density, enhanced electrical performance, and so forth. Additionally, the wafer structure and corresponding methodology are cost-effective, readily implemented, and adaptable to existing assembly and packaging tools and techniques.

Although the preferred embodiments of the invention have been illustrated and described in detail, it will be readily apparent to those skilled in the art that various modifications may be made therein without departing from the spirit of the invention or from the scope of the appended claims. For example, the process operations following wafer bonding can be performed in a differing order then that which was presented.

1. A method of forming electronic component packages comprising:
placing a plurality of first electronic components in a first array;
at least partially encapsulating said first array in a first mold material to form a first panel of said first electronic components;
placing a plurality of second electronic components in a second array;
at least partially encapsulating said second array in a second mold material to form a second panel of said second electronic components;
bonding a surface of said second panel to an outer surface of said first panel to form a stacked panel structure; and
dicing said stacked panel structure to produce said electronic component packages, each of said electronic component packages including one of said first electronic components and one of said second electronic components.

2. A method as claimed in claim 1 further comprising dicing a wafer structure that includes said plurality of first electronic components to produce separated ones of said first electronic components for placement in said first array.

3. A method as claimed in claim 2 wherein:
said wafer structure comprises a sensor wafer structure that includes a sensor wafer and a cap wafer, said first electronic components include sensors located on said sensor wafer, a first inner surface of said cap wafer is coupled to a second inner surface of said sensor wafer, a first one of said cap wafer and said sensor wafer includes a substrate portion with first bond pads associated with said sensors being formed on a corresponding one of said first and second inner surfaces, and a second one of said cap wafer and said sensor wafer conceals said substrate portion; and
said dicing said wafer structure includes dicing said sensor wafer structure to produce sensor structures for placement in said first array, each of said sensor structures including one of said sensors with corresponding ones of said first bond pads.

4. A method as claimed in claim 3 wherein said sensor wafer structure further includes forming seal members extending between said sensor wafer and said cap wafer, at least a portion of said seal members being positioned between said first bond pads and saw lines of said sensor wafer structure, said seal members shielding said first bond pads from contaminants when said wafer structure is diced along said saw lines.

5. A method as claimed in claim 2 wherein said wafer structure is a first wafer structure, and said method further comprises dicing a second wafer structure that includes a plurality of third electronic components to produce separated ones of said third electronic components for placement in said first array such that following said dicing of said stacked panel structure, said each of said electronic component packages further includes one of said third electronic components laterally spaced apart from said one of said first electronic components.

6. A method as claimed in claim 1 further comprising dicing a wafer structure that includes said plurality of said second electronic components to produce separated ones of said second electronic components for placement into said second array.

7. A method as claimed in claim 1 wherein:
said placing said first electronic components in said first array comprises distributing said first electronic components in said first array to align with said second electronic components in said second array; and
said placing said second electronic components in said second array comprises distributing said second electronic components in said second array to align with said first electronic components in said first array.

8. A method as claimed in claim 1 wherein:
a first surface area of each of said first electronic components differs from a second surface area of each of said second electronic components; and
said dicing operation comprises dicing along dicing perimeters defined by a larger one of said first and second surface areas.

9. A method as claimed in claim 1 wherein said dicing operation comprises:
producing a first composite structure that includes said one of said first electronic components at least partially encapsulated by said first mold material, said one of said first electronic components exhibiting a first surface area, and said first composite structure exhibiting a second surface area that is greater than said first surface area; and
producing a second composite structure bonded to said first composite structure, said second composite structure including one of said second electronic components at least partially encapsulated by said second mold material, said one of said second electronic components exhibiting a third surface area that differs from said first surface area of said one of said first electronic components, and said second composite structure exhibiting a fourth surface area that is approximately equivalent to said second surface area of said first composite structure.

10. A method as claimed in claim 1 wherein each of said first electronic components includes first bond pads, said first bond pads are concealed by at least one of said second panel and a portion of said first panel, each of said second electronic components includes a top side exposed out of said second mold material, said each of said second electronic components includes second bond pads formed on said top side, and said method further comprises:
following said bonding operation, removing a material section from said at least one of said second panel and said portion of said first panel of said stacked panel structure to expose said first bond pads; and
forming electrical interconnects between said first and second bond pads.

11. A method as claimed in claim 10 wherein said forming said electrical interconnects is performed prior to said dicing operation.

12. A method as claimed in claim 10 further comprising:
applying a packaging material over said second panel to at least partially encapsulate said second electronic components and said electrical interconnects; and
performing said dicing operation following said applying operation.

13-17. (canceled)

18. A method of forming electronic component packages comprising:
forming a first panel comprising:
dicing a first wafer structure that includes a plurality of first electronic components to produce separated ones of said first electronic components;
placing said first electronic components in a first array; and
at least partially encapsulating said first array in a first mold material to form said first panel;
forming a second panel comprising:
dicing a second wafer structure that includes a plurality of second electronic components to produce separated ones of said second electronic components;
placing said second electronic components in a second array; and
at least partially encapsulating said second array in a second mold material to form said second panel;
bonding a surface of said second panel to an outer surface of said first panel to form a stacked panel structure; and
dicing said stacked panel structure to produce said electronic component packages, each of said electronic component packages including one of said first electronic components and one of said second electronic components.

19. A method as claimed in claim 18 wherein said dicing said stacked panel structure comprises:
producing a first composite structure that includes said one of said first electronic components at least partially encapsulated by said first mold material, said one of said first electronic components exhibiting a first surface area, and said first composite structure exhibiting a second surface area that is greater than said first surface area; and
producing a second composite structure bonded to said first composite structure, said second composite structure including said one of said second electronic components at least partially encapsulated by said second mold material, said one of said second electronic components exhibiting a third surface area that differs from said first surface area, and said second composite structure exhibiting a fourth surface area that is approximately equivalent to said second surface area of said first composite structure.

20. A method as claimed in claim 18 wherein:
a first surface area of each of said first electronic components differs from a second surface area of each of said second electronic components; and
said dicing said stacked panel structure comprises dicing along dicing perimeters defined by a larger one of said first and second surface areas.

21. A method of forming electronic component packages comprising:
placing a plurality of first electronic components in a first array;
at least partially encapsulating said first array in a first mold material to form a first panel of said first electronic components;
placing a plurality of second electronic components in a second array, wherein said placing said first electronic components in said first array comprises distributing said first electronic components in said first array to align with said second electronic components in said second array, and said placing said second electronic components in said second array comprises distributing said second electronic components in said second array to align with said first electronic components in said first array;
at least partially encapsulating said second array in a second mold material to form a second panel of said second electronic components;
bonding a surface of said second panel to an outer surface of said first panel to form a stacked panel structure; and
dicing said stacked panel structure to produce said electronic component packages, each of said electronic component packages including one of said first electronic components and one of said second electronic components, wherein a first surface area of each of said first electronic components differs from a second surface area of each of said second electronic components, and said dicing operation comprises dicing along dicing perimeters defined by a larger one of said first and second surface areas.

22. A method as claimed in claim 21 wherein said dicing operation comprises:
producing a first composite structure that includes said one of said first electronic components at least partially encapsulated by said first mold material, said one of said first electronic components exhibiting a first surface area, and said first composite structure exhibiting a second surface area that is greater than said first surface area; and
producing a second composite structure bonded to said first composite structure, said second composite structure including one of said second electronic components at least partially encapsulated by said second mold material, said one of said second electronic components exhibiting a third surface area that differs from said first surface area of said one of said first electronic components, and said second composite structure exhibiting a fourth surface area that is approximately equivalent to said second surface area of said first composite structure.

23. A method as claimed in claim 21 wherein each of said first electronic components includes first bond pads, said first bond pads are concealed by at least one of said second panel and a portion of said first panel, each of said second electronic components includes a top side exposed out of said second mold material, said each of said second electronic components includes second bond pads formed on said top side, and said method further comprises:
following said bonding operation, removing a material section from said at least one of said second panel and said portion of said first panel of said stacked panel structure to expose said first bond pads; and
forming electrical interconnects between said first and second bond pads.

24. A method as claimed in claim 23 wherein said forming said electrical interconnects is performed prior to said dicing operation.

25. A method as claimed in claim 23 further comprising:
applying a packaging material over said second panel to at least partially encapsulate said second electronic components and said electrical interconnects; and
performing said dicing operation following said applying operation.
